(19) United States
(12) Patent Application Publication
(10) Pub. No.: US 2025/0072290 A1
(43) Pub. Date: Feb. 27, 2025

(54) DUAL MANUFACTURING PROCESS AND CALIBRATION TO ACHIEVE HIGH ACCURACY THERMAL COUPLE SUBSTRATES

(71) Applicant: Applied Materials, Inc., Santa Clara, CA (US)

(72) Inventors: Aaron LU, Tainan City (TW); William CHANG, Santa Clara, CA (US); Jacky J. LIN, Tainan City (TW); Hsiang AN, San Jose, CA (US)

(21) Appl. No.: 18/809,681

(22) Filed: Aug. 20, 2024

Related U.S. Application Data
(60) Provisional application No. 63/578,708, filed on Aug. 25, 2023.

(51) Int. Cl. H10N 10/17; G01K 15/00; H10N 10/01; H10N 10/82

(52) U.S. Cl. CPC H10N 10/17; G01K 15/005; H10N 10/01; H10N 10/82

(57) ABSTRACT

Embodiments herein are generally directed to a system and process for manufacturing temperature measurement devices for use in semiconductor and display manufacturing. A bifurcated thermocouple substrate is provided and includes a primary substrate with a substrate aperture, a secondary substrate disposed within the substrate aperture, and a thermocouple disposed within a thermocouple aperture of the secondary substrate. A method of calibrating a bifurcated thermocouple substrate includes placing a secondary substrate with an embedded thermocouple of a bifurcated thermocouple substrate into a calibrator, heating the calibrator, the secondary substrate, and the thermocouple to a number “n” of temperature points and recording the temperature readings of the calibrator and the thermocouple The method includes then performing a mathematical conversion using the recorded temperature readings, storing using the stored mathematical conversion to correct thermocouple readings during use in a substrate processing chamber.

### RELATED APPLICATIONS

This application claims benefit of and priority to U.S. Provisional Application No. 63/578,708 filed Aug. 24, 2023 which is herein incorporated in it entirety by reference for all purposes.

### BACKGROUND

### Field

Embodiments of the present disclosure generally relate to a system and process for manufacturing temperature measurement devices for use in both semiconductor and display manufacturing.

### Description of the Related Art

A thermocouple substrate serves as the supporting material for the two wires of a thermocouple, which necessitates it to possess qualities of electrical insulation and effective thermal conductivity. Furthermore, chemical non-reactivity of the thermocouple substrate with the thermocouple wires is of paramount importance.

Diverse materials find application as thermocouple substrates, encompassing ceramics, metals, and polymers. Ceramics offer an advantageous choice due to their combination of electrical insulation, substantial thermal conductivity, and chemical inertness. Varieties like alumina, zirconia, and mullite are common ceramic substrates. Metals also enter the fray, but careful selection is essential to prevent any undesirable chemical reactions with the thermocouple wires. Stainless steel, nickel, and copper stand out as familiar metal substrate options. In scenarios where lower temperatures prevail, polymers emerge as a fitting option. Their attributes of electrical insulation, commendable thermal conductivity, and lightweight nature make them suitable. Examples of polymer substrates encompass polyimide, polyethylene, and polypropylene.

Manufacturing of thermocouple substrates encompasses various methods, such as extrusion, injection molding, and screen printing. Extrusion entails melting the substrate material and extruding it through a die to create a continuous tube. Injection molding involves melting the substrate material, injecting it into a mold, and subsequently removing the cooled substrate. Screen printing employs a thin ink layer containing thermocouple wires, which is applied onto the substrate material and then cured to establish a lasting bond.

Calibration of thermocouple substrates involves measuring their output voltage at a known temperature, facilitated by a thermocouple calibrator. The calibrator subjects the substrate to a known temperature and gauges the thermocouple's output voltage, thus generating calibration data for temperature conversion.

In the realm of semiconductor and display manufacturing, thermocouple substrates prove indispensable for monitoring wafer, glass or substrate temperature during plasma-enhanced chemical vapor deposition (PECVD), a process that deposits thin material films on substrate surfaces. The precision of the substrate temperature during PECVD is crucial for the resulting film's properties. Thermocouple substrates, bonded to the substrate using a bonding agent and connected to a temperature controller, facilitate this monitoring process. The temperature controller adjusts reactor power to uphold the desired substrate temperature, ensuring optimal film quality.

The advantages of utilizing thermocouple substrates in semiconductor and display manufacturing are manifold. They offer precise and dependable temperature measurements, ease of use and installation, cost-effectiveness, and adaptability to diverse manufacturing processes. Nevertheless, issues affecting their accuracy in PECVD include heat transfer, chemical reactions, physical damage, and improper calibration. These issues can lead to inaccurate temperature readings, process instability, increased costs, and safety hazards.

Accordingly, there is a need for improved manufacturing and calibration of thermocouple substrates that address these concerns to ensure the effectiveness and safety of substrate processing.

### SUMMARY

Embodiments herein are generally directed to a system and process for manufacturing temperature measurement devices for use in semiconductor and display manufacturing. More particularly, the present disclosure is directed to systems and methods for manufacturing thermocouple substrates for use in semiconductor and display processing.

In an embodiment, a bifurcated thermocouple substrate is provided. The bifurcated thermocouple substrate includes a primary substrate with a substrate aperture, a secondary substrate disposed within the substrate aperture, and a thermocouple disposed within a thermocouple aperture of the secondary substrate. The primary substrate and the secondary substrate include matching bonding apertures configured to bond the secondary substrate to the primary substrate using wire bonding. The thermocouple and the secondary substrate include a strain relief mechanism.

In another embodiment, a method of producing a thermocouple substrate is provided. The method includes inserting a thermocouple into a thermocouple aperture of a secondary substrate, calibrating the thermocouple and secondary substrate, and inserting the secondary substrate into a substrate aperture of a primary substrate. The method further includes adding strain relief to the thermocouple and secondary substrate and performing a thermal cycle test on the thermocouple substrate.

In yet another embodiment, a method of calibrating a bifurcated thermocouple substrate is provided. The method includes placing a secondary substrate with an embedded thermocouple of a bifurcated thermocouple substrate into a calibrator, validating an accuracy of the calibrator to within a desired range, heating the calibrator, the secondary substrate, and the thermocouple to a number “n” of temperature points and recording the temperature readings of the calibrator and the thermocouple The method includes then performing a mathematical conversion such as linear regression, using a controller, using the recorded temperature readings of the calibrator and the thermocouple, storing the linear regression using the controller, and using the stored mathematical conversion such as linear regression to correct thermocouple readings, via the controller, from the bifurcated thermocouple substrate during use in a substrate processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1 illustrates a schematic, cross-sectional side view of a processing chamber, according to certain embodiments.

FIG. 2A illustrates a schematic top view of a bifurcated thermocouple substrate, according to certain embodiments.

FIG. 2B illustrates a schematic, cross-sectional side view of the bifurcated thermocouple substrate and the thickness difference of FIG. 2A, according to certain embodiments.

FIG. 3 illustrates a method of producing a bifurcated thermocouple substrate, according to certain embodiments.

FIGS. 4A-4D illustrate a primary substrate and secondary substrate undergoing the method of FIG. 3, according to certain embodiments.

FIG. 5 illustrates a method of calibrating a bifurcated thermocouple substrate, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to a system and process for manufacturing temperature measurement devices for use in semiconductor and display manufacturing. More particularly, the present disclosure is directed to systems and methods for manufacturing thermocouple substrates for use in semiconductor and display processing.

In semiconductor and display manufacturing, the indispensability of thermocouple substrates for monitoring wafer and glass temperature during plasma-enhanced chemical vapor deposition (PECVD), a process involving the deposition of thin material films on wafer surfaces, is well recognized. The precision of wafer temperature is of utmost importance for determining the properties of the resultant films. The monitoring process is facilitated by thermocouple substrates, which are affixed to the wafer and glass through a bonding agent and connected to a temperature controller. The temperature controller, in turn, undertakes the adjustment of reactor power to sustain the desired wafer temperature, thereby ensuring the attainment of optimal film quality.

The manufacturing techniques for thermocouple substrates encompass a range of methodologies, including extrusion, injection molding, and screen printing. Extrusion necessitates the melting of the substrate material, which is then extruded through a die to form a continuous tube. Conversely, injection molding involves the melting of the substrate material, its injection into a mold, and subsequent extraction of the cooled substrate. Meanwhile, screen printing employs a thin layer of ink infused with thermocouple wires, applied to the substrate material and cured to establish a durable bond.

The calibration process of thermocouple substrates involves measuring their output voltage at a predetermined temperature range, facilitated through a thermocouple calibrator. By subjecting mathematically converting the substrate to the known temperature and measuring the thermocouple's output voltage, calibration data for temperature conversion is generated. Despite the manifold benefits that thermocouple substrates offer in semiconductor and display manufacturing, encompassing precise temperature measurements, user-friendly installation, cost-effectiveness, and adaptability to diverse manufacturing processes, certain challenges perturb their accuracy in PECVD. These encompass concerns related to heat transfer, chemical reactions, physical degradation, and incorrect calibration. The resolution of these issues is pivotal in guaranteeing the efficacy and safety of PECVD processes.

Currently, thermocouple substrates, such as those with a K-type thermocouple, have an accuracy that is about +/−0.75% of temperature reading. When the measured temperature reaches 400° C., the accuracy would be approximately +/−3° C. However, with rising demands for high-accuracy applications, +/−3° C. at 400° C. is no longer accurate enough for product manufacturing. Other types of thermocouples, such as J-type or N-type, have limited operating conditions and markedly higher costs.

The present disclosure provides for a two-piece or bifurcated thermocouple substrate. A first substrate is embedded with a thermocouple, and is calibrated to an accurate temperature reading. Then the first substrate is mounted to a second substrate. The resulting accuracy is within +/−0.4° C. or less, including manufacture deviation. The two-piece thermocouple substrate significantly reduces accuracy deviation from the manufacturing process as compared to previous thermocouple substrates, and increases the overall accuracy. In addition, the two-piece design has less rework cost whenever one substrate is broken.

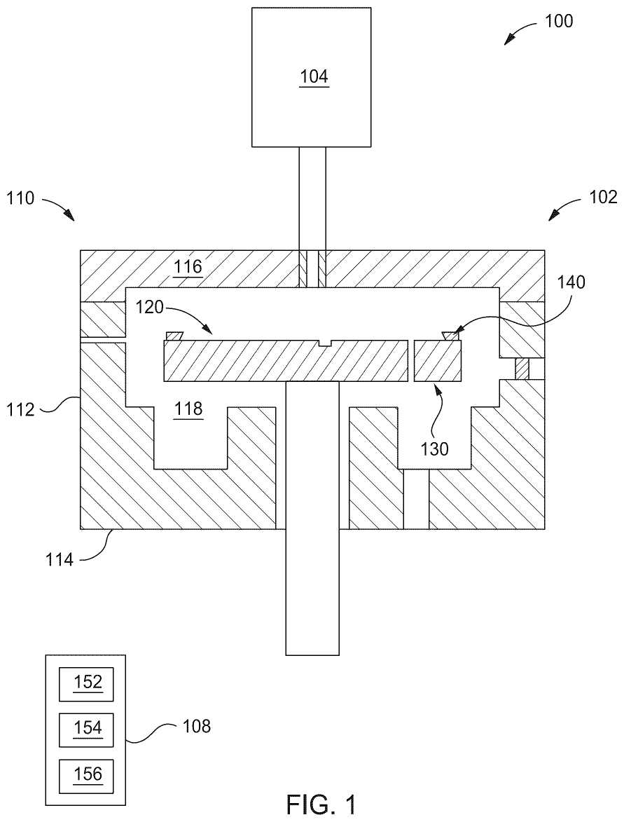

FIG. 1 illustrates a substrate processing chamber 100 including a processing volume 118, a substrate support 130 disposed within the processing volume 118, and at least one bifurcated thermocouple substrate 140 disposed on the substrate support 130. The bifurcated thermocouple substrate 140 is disposed on a surface of the substrate support 130 configured to contact a substrate during processing.

As shown in FIG. 1, the processing system 100 includes the processing chamber 102, a gas delivery system 104 fluidly coupled to the processing chamber 102, and a system controller 108. The processing chamber 102 includes a chamber lid assembly 110, one or more sidewalls 112, and a chamber base 114, which collectively define a processing volume 118. The chamber lid assembly 110 includes a lid plate 116 which faces the substrate support 130 disposed in the processing volume 118. Here, the gas delivery system 104 is fluidly coupled to the processing chamber 102. Processing or cleaning gases delivered, by use of the gas delivery system 104, flow into the processing region 120.

In some embodiments, the substrate support 130 further includes a bifurcated thermocouple substrate 140 disposed on the substrate support 130. The bifurcated thermocouple substrate is used on the substrate support 130 to measure the temperature of a substrate. The bifurcated thermocouple substrate 140 is typically made of a material that is resistant to high temperatures and chemicals, such as glass, quartz, or silicon carbide. The thermocouple wires are bonded to the bifurcated thermocouple substrate 140 in a way that minimizes the thermal resistance between the wires and the bifurcated thermocouple substrate 140.

The bifurcated thermocouple substrate 140 is mounted to places on substrate support 130 to allow the thermocouple wires (not shown) to be connected to a temperature measurement device. The temperature measurement device can be a digital multimeter, a data logger, or a computer-controlled system such as the controller 108.

Operation of the processing system 100 is facilitated by the system controller 108. The system controller 108 includes a programmable central processing unit, here a CPU 152, which is operable with a memory 154 (e.g., non-volatile memory) and support circuits 156. The CPU 152 is one of any form of general-purpose computer processor used in an industrial setting, such as a programmable logic controller (PLC), for controlling various chamber components and sub-processors. The memory 154, coupled to the CPU 152, facilitates the operation of the processing chamber. The support circuits 156 are conventionally coupled to the CPU 152 and comprise cache, clock circuits, input/output subsystems, power supplies, and the like, and combinations thereof coupled to the various components of the processing system 100 to facilitate control of substrate processing operations therewith.

Here, the instructions in memory 154 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

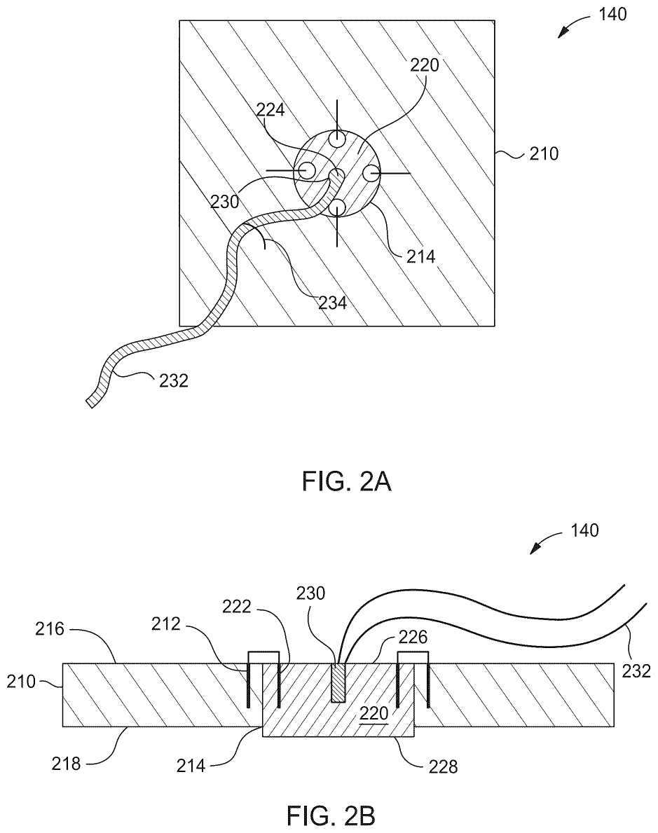

FIGS. 2A and 2B illustrate the bifurcated thermocouple substrate 140. Specifically, FIG. 2A illustrates a schematic top view of the bifurcated thermocouple substrate 140, and FIG. 2B illustrates a schematic, cross-sectional side view of the bifurcated thermocouple substrate 140.

As shown in FIG. 2A, the bifurcated thermocouple substrate 140 includes a primary substrate 210 and a secondary substrate 220. The primary substrate 210 includes a substrate aperture 214 where the secondary substrate 220 is disposed. The primary substrate 210 and the secondary substrate 220 include matching bonding apertures, e.g., primary bonding apertures 212 and secondary bonding apertures 222, configured to bond the primary substrate 210 and the secondary substrate 220 together using wire bonding. The primary substrate 210 and secondary substrate 220 may be bonded together using other methods, such as adhesive bonding, that may not require the use of the primary bonding apertures 212 or the secondary bonding apertures 222. The secondary substrate 220 also includes a thermocouple aperture 224 with a thermocouple 230 disposed therein. The thermocouple 230 may include a thermocouple connection 232 to a controller, such as the controller 108. To reduce the strain on the thermocouple 230, a strain relief 234 may be employed to secure the thermocouple connection 232 to the primary substrate 210.

As shown in FIG. 2B, the primary substrate 210 includes a top surface 216, a bottom surface 218 opposite the top surface 216, and a substrate aperture 214 through the body of the primary substrate 210. The substrate aperture 214 includes an inner surface that extends the entire thickness of the primary substrate 210. The secondary substrate 220 includes a top surface 226, a bottom surface 228, and is disposed within the substrate aperture 214 and in direct contact with the inner surface of the substrate aperture 214. The top surface 226 of the secondary substrate 220 is planar to or flush with the top surface 216 of the primary substrate 210. The bottom surface 228 of the secondary substrate 220 extends beyond the bottom surface 218 of the primary substrate 210. In other words, the secondary substrate 220 has a thickness that is thicker than the thickness of the primary substrate 210. The thickness of the secondary substrate 220 is at least 5% greater than the thickness of the primary substrate 210, such as 10% greater. For example, the primary substrate 210 may have a thickness of about 0.5 millimeters (mm), and the secondary substrate 220 may have a thickness of about 0.55 mm.

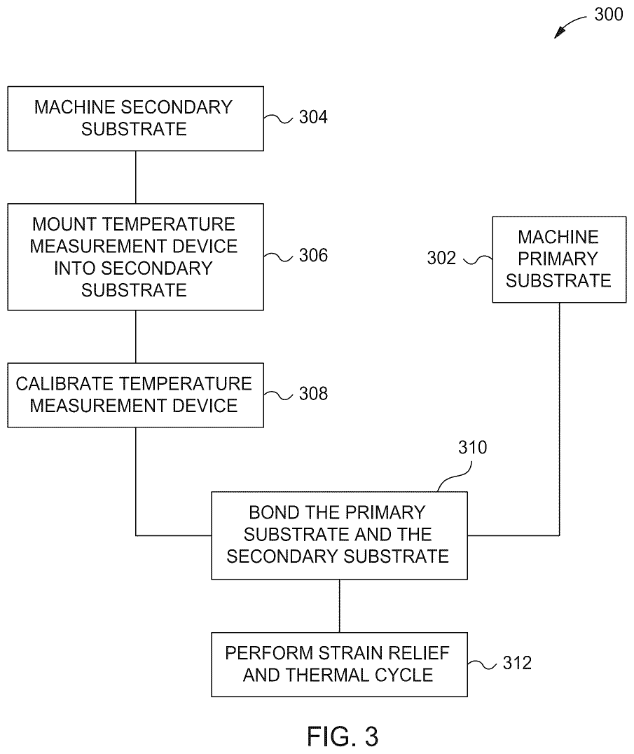

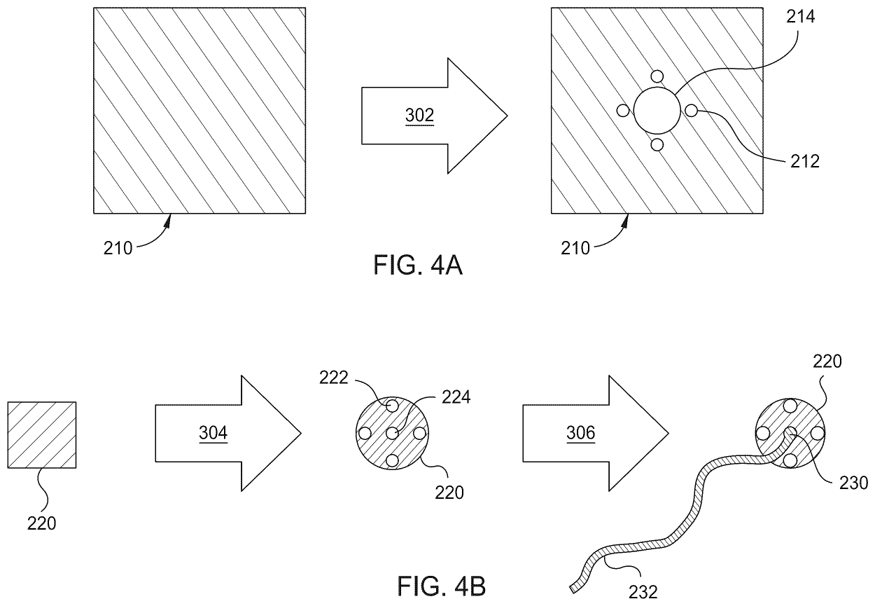

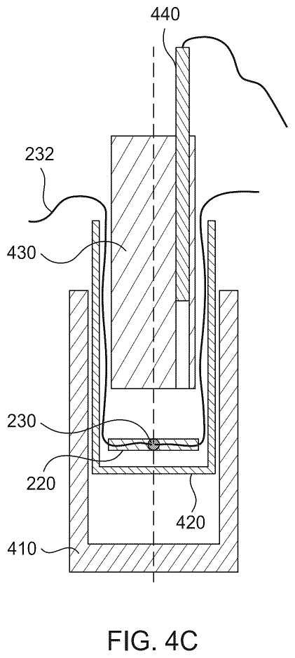

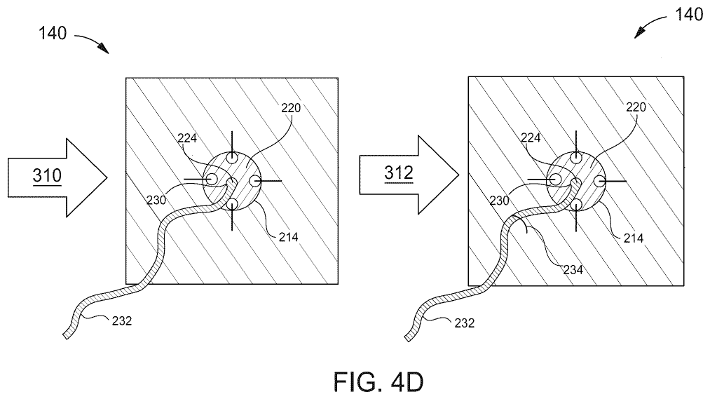

FIG. 3 illustrates a method 300 for manufacturing a bifurcated thermocouple substrate 140. FIGS. 4A-4D illustrate a bifurcated thermocouple substrate 140 undergoing the method 300. At operation 302, as shown in FIG. 4A, a primary substrate 210 is machined to create a substrate aperture 214 through the body of the primary substrate 210 and a plurality of bonding apertures in the top surface 216 of the primary substrate 210. The substrate apertures 214 and the plurality of bonding apertures may be any desired shape, such as circular or rectangular.

At operation 304, as shown in FIG. 4B, a secondary substrate 220 is machined to make a small round substrate to fit into the substrate aperture 214 of the primary substrate 210. The secondary substrate 220 includes a diameter that matches the diameter of the substrate aperture 214. For example, the substrate aperture 214 and the secondary substrate 220 may have a diameter of 20 mm. Alternatively, the diameter of the secondary substrate 220 may be smaller than the substrate aperture 214 of the primary substrate 210 by between about 0.5% and about 4%, such as about 1% and about 3%. For example, the substrate aperture 214 may have a diameter of 20 mm and the secondary substrate 220 may have a diameter of 19.5 mm, equivalent to 2.5% smaller than the substrate aperture 214. The secondary substrate 220 may also include bonding apertures in its top surface 226 to match the bonding apertures of the primary substrate 210. Alternatively, in embodiments where wire bonding is not used, the secondary substrate 220 may not include the bonding apertures.

The secondary substrate 220 includes a thermocouple aperture 224 configured to receive and secure a thermocouple. At operation 306, as shown in FIG. 4B, the secondary substrate 220 is embedded with a thermocouple 230 by inserting the thermocouple 230 into the thermocouple aperture 224.

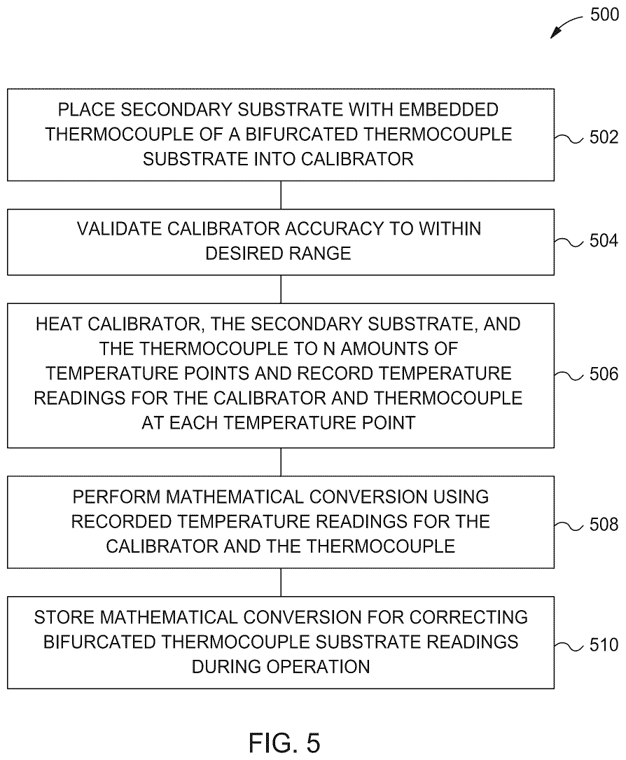

At operation 308, the secondary substrate 220 is calibrated. As shown in FIG. 4C, the secondary substrate 220 is inserted into a first holder 420 of a calibrator 410. A second holder 430 containing a calibration sensor 440 is then placed over the secondary substrate 220. The thermocouple 230 embedded in the secondary substrate 220 is then calibrated to the calibration sensor 440 of the calibrator 410 to achieve accuracy of within +/−0.4° C. or less at 400° C. The calibration method is further discussed in reference to FIG. 5.

At operation 310, as shown in FIG. 4D, after the secondary substrate 220 is calibrated, the secondary substrate 220 is placed within the substrate aperture 214 of the primary substrate 210 and bonded using fine metal wire to connect the bonding apertures of the secondary substrate 220 to the bonding apertures of the primary substrate 210. This wire bonding between the primary substrate 210 and the secondary substrate 220 ensures that the secondary substrate 220 is secured within the primary substrate 210. Further, the top surface 226 of the secondary substrate 220 and the top surface 216 of the primary substrate 210 are mounted flush to each other, such that the bottom surface 228 of the secondary substrate 220 protrudes beyond the bottom surface 218 of the primary substrate 210 due to the thickness variation between the primary substrate 210 and the secondary substrate 220. This protrusion ensures that the calibrated secondary substrate 220 and embedded thermocouple 230 make contact with the measuring target, such as a semiconductor and display substrate on a substrate support; furthermore, the protrusion also ensures the weight of primary substrate 210 and secondary substrate 220 concentrate on the bottom surface 228 of the secondary substrate 220, and produce accurate temperature measurements.

At operation 312, as shown in FIG. 4D, strain relief 234 is added to the bifurcated thermocouple substrate 140, and the thermocouple substrate 140 undergoes a thermal cycle test ranging from between 25° C. to about 400° C. Strain relief is employed as a means to mitigate or minimize stress or strain experienced by the thermocouple substrate 140 during the manufacturing process. This holds significance due to the potential for stress or strain to inflict harm upon the thermocouple 230, resulting in imprecise temperature measurements.

Several avenues are available for achieving strain relief in the manufacturing of thermocouple substrates 140. One approach involves the utilization of a support structure for the thermocouple 230, securing the thermocouple 230 to the secondary substrate 220, the primary substrate 210, or both. This support structure, whether composed of metal or plastic, serves to restrain the thermocouple 230 from undergoing flexing or movement.

Additionally, the implementation of a strain relief sleeve might be used in certain instances. Positioned around the thermocouple 230, this sleeve aids in the absorption of any stress or strain that might be exerted on the thermocouple substrate 140.

The selection of a suitable strain relief method hinges upon the specific application and the thermocouple 230 material in use for safeguarding the thermocouple 230 from harm and upholding the precision of temperature readings.

A thermal cycle test is executed on thermocouple substrates 140 to ascertain their ability to endure the thermal stresses anticipated in their application. The thermocouple substrate 140 is subjected to repeated cycles of heating and cooling, typically spanning from room temperature to the substrate's maximum operating temperature.

The significance of the thermal cycle test lies in its capacity to detect latent vulnerabilities within the substrate that might result in failure. For instance, it can uncover susceptibilities like cracking or delamination stemming from thermal expansion and contraction.

The outcomes of the thermal cycle test inform the substrate's suitability. Substrate failure in the test could necessitate substrate redesign or the adoption of an alternative material. The benefits inherent in performing a thermal cycle test on thermocouple substrates 140 encompass the identification of latent weaknesses that might lead to failure, assurance of substrate resilience against projected thermal stresses, and enhancement of substrate reliability.

FIG. 5 illustrates a method 500 for calibration of a secondary substrate 220 of a bifurcated thermocouple substrate 140. The method begins at operation 502 by placing a secondary substrate 220 fitted or embedded with a thermocouple 230 into a calibrator 410. The thermocouple 230 may be a K-type or other type of thermocouple. Placing the secondary substrate 220 with the embedded thermocouple 230 into the calibrator 410 may include placing the secondary substrate 220 in a first holder 420 of the calibrator 410 then placing a second holder 430 containing a calibration sensor 440 on top of the secondary substrate 220. A gap exists between the first holder 420 and the second holder 430 such that thermocouple connections of the embedded thermocouple 230 may exit the calibrator 410 to couple to the controller.

At operation 504, the calibrator 410 accuracy is validated to within a desired range by the calibration sensor 440, such as within +/−0.3° C. At operation 506, the calibrator 410 and the secondary substrate 220 are heated to a number “n” of temperature points, such as three, and the temperature readings of both the calibrator 410 and the thermocouple 230 are recorded.

At operation 508, a mathematical conversion such as linear regression is performed by a controller using the recorded temperature readings from the calibrator 410 and the recorded temperature readings from the thermocouple 230. The application of mathematical conversion such as linear regression enables the modeling of relationships between variables. In the specific context of temperature calibration, this method is employed to establish a connection between the thermocouple temperature and the calibrator temperature.

The mathematical conversion such as linear regression equation, represented as y=mx+b, holds the following meanings for its components: the thermocouple 230 temperature is denoted as y, the calibrator 410 temperature is represented by x, the slope of the line is characterized as m, and the y-intercept is symbolized as b.

The slope, indicated as m, clarifies the extent of change experienced in the thermocouple 230 temperature with a unit change in the calibrator 410 temperature. The y-intercept, b, signifies the value of y when x is zero.

To execute linear regression for temperature calibration, the initial step involves gathering a dataset incorporating both thermocouple 230 and calibrator 410 temperatures. Following data collection, software is employed to fit the linear regression equation to the dataset. The output from the software provides values for m and b, which are subsequently used for calibrating the thermocouple 230.

The process of implementing linear regression for temperature calibration includes collecting a dataset comprising data points that represent both thermocouple 230 and calibrator 410 temperatures, utilizing software to align the linear regression equation with the dataset, calculating the values of m and b, and applying the derived m and b values for temperature sensor calibration.

At operation 510, the linear regression is then stored such that it can be recalled during operation of the bifurcated thermocouple substrate 140 to correct the readings recorded by the thermocouple, for example, during substrate processing in a processing chamber. The linear regression may be stored in a controller coupled to the processing chamber and the bifurcated thermocouple substrate 140, e.g., in a memory of the controller. The controller may, by using a processor, correct raw readings from the bifurcated thermocouple substrate 140 using the stored linear regression. This stored linear regression and calibration method allows for improved accuracy

The present disclosure provides for a system and method for producing a bifurcated thermocouple substrate. The present disclosure provides a thermal reading accuracy that is within +/−0.4° C. or less at 400° C. The bifurcated thermocouple substrate of the present disclosure eliminates the accuracy deviation that occurs during the manufacturing process and thermocouple deviation. The present disclosure provides increased contact pressure to firmly contact a target, such as a substrate disposed on the bifurcated thermocouple substrate. Further, the bifurcated design provides for less rework or repair cost whenever one of the primary or secondary substrates is broken.

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

What is claimed is:

1. A bifurcated thermocouple substrate, comprising:
a primary substrate having a substrate aperture disposed therethrough;
a secondary substrate disposed within the substrate aperture; and
a thermocouple disposed within a thermocouple aperture of the secondary substrate.

2. The bifurcated thermocouple substrate of claim 1, wherein the secondary substrate comprises a thickness that is greater than a thickness of the primary substrate by at least 5%.

3. The bifurcated thermocouple substrate of claim 1, wherein the primary substrate and the secondary substrate comprise matching bonding apertures configured to bond the secondary substrate to the primary substrate using wire bonding.

4. The bifurcated thermocouple substrate of claim 1, wherein the thermocouple and the secondary substrate comprise a strain relief mechanism.

5. The bifurcated thermocouple substrate of claim 1, wherein the secondary substrate has a diameter that is smaller than a diameter of the substrate aperture by about 1% to about 3%.

6. The bifurcated thermocouple substrate of claim 1, wherein the thermocouple and the secondary substrate are calibrated such that an accuracy of the bifurcated thermocouple substrate is about +/−0.4° C. or less at 400° C.

7. The bifurcated thermocouple substrate of claim 6, wherein the thermocouple and the secondary substrate are calibrated prior to being disposed within the substrate aperture.

8. A method of producing a thermocouple substrate, comprising:
(a) inserting a thermocouple into a thermocouple aperture of a secondary substrate;
(b) calibrating the thermocouple and secondary substrate; and
(c) inserting the secondary substrate into a substrate aperture of a primary substrate.

9. The method of claim 8, further including;
(d) adding strain relief to the thermocouple and secondary substrate; and
(e) performing a thermal cycle test on the thermocouple substrate.

10. The method of claim 9, wherein the strain relief is a support structure securing the thermocouple to the secondary substrate.

11. The method of claim 8, wherein inserting the secondary substrate into the substrate aperture includes bonding the secondary substrate to the primary substrate via wire bonding.

12. The method of claim 8, wherein the secondary substrate comprises a diameter that is less than a diameter of the substrate aperture by about 1% to about 3%.

13. The method of claim 8, wherein the secondary substrate comprises a thickness that is thicker than a thickness of the primary substrate by about 5% or more.

14. The method of claim 8, wherein calibrating the thermocouple and secondary substrate comprises using a mathematical conversion to correct temperature readings of the thermocouple.

15. A method of calibrating a bifurcated thermocouple substrate, comprising:
(a) placing a secondary substrate with an embedded thermocouple of a bifurcated thermocouple substrate into a calibrator;
(b) validating an accuracy of the calibrator to within a desired range;
(c) heating the calibrator, the secondary substrate, and the thermocouple to a number “n” of temperature points and recording the temperature readings of the calibrator and the thermocouple;
(d) performing a mathematical conversion, using a controller, using the recorded temperature readings of the calibrator and the thermocouple;
(e) storing the mathematical conversion using the controller; and
(f) using the stored mathematical conversion to correct thermocouple readings, via the controller, from the bifurcated thermocouple substrate during use in a substrate processing chamber.

16. The method of claim 15, wherein the accuracy of the calibrator is validated to within 0.3° C. at 400° C.

17. The method of claim 15, wherein the mathematical conversion corrects the temperature readings of the thermocouple to the temperature readings.

18. The method of claim 15, wherein the number “n” of temperature points comprises three temperature points.

19. The method of claim 15, wherein the thermocouple is a K-type thermocouple.

20. The method of claim 15, wherein placing the secondary substrate and the thermocouple into the calibrator includes placing the secondary substrate in a first holder of the calibrator and then placing a second holder containing a calibration sensor on top of the secondary substrate.
